(19) United States
(12) Patent Application Publication
(10) Pub. No.: US 2009/0150623 A1
(43) Pub. Date: Jun. 11, 2009

(54) SEMICONDUCTOR DEVICE AND TEST MODE CONTROL CIRCUIT

(75) Inventor: Kazuki Yoshioka, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/064,540

(22) PCT Filed: Aug. 7, 2006
(86) PCT No.: PCT/JP2006/315608

§ 371 Date: Feb. 22, 2008

(30) Foreign Application Priority Data
Aug. 30, 2005 (JP) 2005-250070

(51) Int. Cl. H03M 13/05; G06F 12/00; G06F 11/08

(52) U.S. Cl. 711/154; 714/777; 711/E12.001; 714/E11.03

(57) ABSTRACT

The present invention provides a semiconductor device which sufficiently ensures the security and prevents the decline of the yield even when the failure or the like causes a bit change in the data of the test mode control flag stored in the nonvolatile memory. The semiconductor device of the present invention includes: a nonvolatile memory which stores a test mode control code in a predetermined address; a generation unit which generates a fixed value indicating permission for or prohibition of a test mode; and a Hamming distance determination circuit which controls switching to the test mode depending on whether or not a Hamming distance between the control code and the fixed value is equal to or less than a predetermined number.

### TECHNICAL FIELD

The present invention relates to semiconductor devices having a test mode, and particularly to a technique for controlling the test mode of a semiconductor device which is required to ensure security.

### BACKGROUND ART

In an LSI loaded with highly-confidential data or a program and with a security circuit for using an IC card and the like, it is necessary to prohibit the use of a test mode after product shipment so as to prevent disclosure and falsification of the data, the program, and circuit information.

As a method for prohibiting the test mode, there is a method in which a test mode control flag that indicates permission for or prohibition of execution of test mode and specific data for comparison are compared, and the test mode is permitted in the case where they match, and the test mode is prohibited in the case where they do not match. The test mode control flag is stored in a predetermined address of a nonvolatile memory in advance.

For example, according to the technique disclosed in Patent Reference 1, a flag which indicates the permission for or the prohibition of the test mode and is stored in EEPROM, a nonvolatile memory, and specific data are compared, and switching to the test mode is prohibited in the case where the flag and the specific data match. In the test mode, it is possible to initialize and program the EEPROM in addition to performing a test operation. Furthermore, it is possible to make the switching to the test mode in the case where the flag and the specific data do not match.

A method for realizing test mode control with the test mode control flag stored in the above-mentioned nonvolatile memory is described. FIG. 1 is a block diagram showing a structure of a conventional test mode control circuit. The conventional test mode control circuit includes a nonvolatile memory 91, a flag holding register 92, a fixed value generation unit 93, a comparison circuit 94, an AND circuit 95, and a test circuit 96.

The nonvolatile memory 91 stores a test mode control flag which specifies the permission for or the prohibition of the execution of test mode. The test mode control flag may be 1 bit or plural bits. The flag holding register 92 holds the test mode control flag read from the nonvolatile memory 91 after the LSI startup. The fixed value generation unit 93 generates a predetermined test mode prohibition code. The comparison circuit 94 compares data of the test mode control flag and the test mode prohibition code and outputs a high level in the case where they match. The AND circuit 95 masks a test signal to the test circuit 96 in the case where the output of the comparison circuit 94 is the high level.

Here, the description proceeds as an example where the test mode prohibition code is assumed to be 5 A (hexadecimal number).

Once the LSI is powered on, the data of the test mode control flag is read from the predetermined address of the nonvolatile memory 91, and the read data is stored in the flag holding register 92.

When the data of the test mode control flag stored in the flag holding register 92 is other than 5 A (hexadecimal number), the output of the comparison circuit 94 becomes a low level. Therefore, since the test signal is inputted to the test circuit 96, the test mode is permitted. On the other hand, when the data of the test mode control flag stored in the flag holding register 92 is 5 A (hexadecimal number), the output of the comparison circuit 94 becomes the high level. Therefore, since the test signal is not inputted to the test circuit 96, the test mode is prohibited.

### Patent Reference 1: Japanese Unexamined Patent Application Laid-Open Publication No. 11-219318

### DISCLOSURE OF INVENTION

### Problems that Invention is to Solve

However, according to the above-mentioned conventional technique, since the test mode is prohibited only when the data of the test mode control flag stored in the nonvolatile memory match to the specific test mode prohibition code, there is a problem that the prohibition of the test mode is lifted in the case where a failure or the like causes the data of the test mode control flag stored in the nonvolatile memory to change even by I bit. As a result, the switching to the test mode allows access to data which requires security such as an authentication code. This increases the chances that the circuit information is disclosed and falsified, and causes a problem that the security cannot be ensured.

On the other hand, in the case where a system in which the test mode is prohibited is employed only when the data of the test mode control flag stored in the nonvolatile memory and the specific test mode prohibition code do not match, LSIs in which the test mode is prohibited right after production are frequently produced when the data of the nonvolatile memory right after production is not determined. When the test mode is prohibited right after production, it is not possible to initialize the nonvolatile memory. This can lead to a problem that a yield of the LSIs is declined.

The present invention has been devised to solve the above-mentioned problems and the like, and it is an object of the present invention to provide a semiconductor device which sufficiently ensures the security and prevents the decline of the yield even when the failure or the like causes a bit change in the data of the test mode control flag stored in the nonvolatile memory.

### Means to Solve the Problems

In order to achieve the above-mentioned object, the semiconductor device of the present invention is a semiconductor device which has a test mode and which includes: a nonvolatile memory which stores a control code in a predetermined address; a generation unit which generates a fixed value; and a control unit which controls switching to the test mode depending on whether or not a Hamming distance between the control code and the fixed value is equal to or less than a predetermined number.

According to this structure, in the case where the Hamming distance is equal to or less than the predetermined number, that is, in the case where a failure or the like causes a bit change in the control code and the number of changed bits is equal to or less than the predetermined number, the switching to the test mode is prohibited or permitted. For example, even in the case where the bit change equal to or less than the predetermined number occurs in the control code which denotes the prohibition of the switching to the test mode, canceling the prohibition of the switching to the test mode is prevented. As a result, the disclosure and falsification of the circuit information are prevented, thereby ensuring the security. Furthermore, even in the case where the bit change equal to or less than the predetermined number occurs in the control code which denotes the permission for the switching to the test mode, the switching to the test mode is not prohibited. Consequently, it is possible to lower the probability that the test mode is prohibited right after production, thereby preventing a decline of the yield.

Here, the control unit may include: a calculation unit which calculates the Hamming distance between the control code and the fixed value generated by the generation unit; a comparison unit which determines whether or not the Hamming distance is equal to or less than the predetermined number by comparing the calculated Hamming distance and the predetermined number; and a prohibition unit which prohibits the switching to the test mode when the Hamming distance is determined to be equal to or less than the predetermined number.

According to this structure, it is possible to structure the control unit by a relatively simple circuit.

Here, an error correction code for correcting the number of bit errors equal to or less than the predetermined number may be added to the control code, and the control unit may include: an error correction unit which performs an error correction processing on the control code by using the error correction code; a comparison unit which determines whether or not the error-corrected control code and the fixed value generated by the generation unit match by comparing the error-corrected control code and the fixed value; and a prohibition unit which prohibits the switching to the test mode when the error-corrected control code and the fixed value are determined to match.

According to this structure, instead of directly calculating the Hamming distance, it is possible to determine whether or not the Hamming distance is equal to or less than the predetermined number by simply comparing the error-corrected control code and the fixed value.

Here, the semiconductor device may further include: a register for storing data; a first setting unit which sets the fixed value, as an initial value, to the register when the semiconductor device is reset; and a second setting unit which reads the control code from the nonvolatile memory and sets the read control code to the register after the semiconductor device is reset. The control unit may control the switching to the test mode according to a Hamming distance between the data held in the register and the fixed value.

According to this structure, in a period from a beginning of the rest till when the control code is set to the register, it is possible to prevent a prohibition state from being canceled. For example, it is possible to prevent the switching to the test mode by abusing the reset signal for disclosing and falsifying the data of the nonvolatile memory.

Here, the semiconductor device may further include a writing unit which writes the fixed value into the nonvolatile memory when the Hamming distance is equal to or less than the predetermined number.

According to this structure, in the case where the bit change equal to or less than the predetermined number occurs in the control code, it is possible to restore such a control code to a correct control code without the bit change, which allows further increase in reliability.

Here, the semiconductor device may include: a memory which stores a program in which a function of the writing unit is described; and a CPU which executes the program. The writing unit may be realized by the execution of the program by the CPU.

Moreover, since the test mode control circuit, the test mode control method, and the program of the present invention also include the above-mentioned structures, they are not described here.

### EFFECTS OF THE INVENTION

According to the present invention, in the case where the Hamming distance is equal to or less than the predetermined number, that is, in the case where a failure or the like causes a bit change in the control code and the number of changed bits is equal to or less than the predetermined number, the switching to the test mode is prohibited or permitted. For example, even in the case where the bit change equal to or less than the predetermined number occurs in the control code which denotes the prohibition of the switching to the test mode, canceling the prohibition of the switching to the test mode is prevented. As a result, the disclosure and falsification of the circuit information are prevented, thereby securing the security. Moreover, even in the case where the bit change equal to or less than the predetermined number occurs in the control code which denotes the permission for the switching to the test mode, the switching to the test mode is not prohibited. Consequently, it is possible to lower the probability that the test mode is prohibited right after production, thereby preventing the decline of the yield.

In addition, it is possible to prevent the switching to the test mode by abusing the reset signal for disclosing and falsifying the data of the nonvolatile memory.

Further, in the case where the bit change equal to or less than the predetermined number occurs in the control code stored in the nonvolatile memory, such test mode control code can be restored to a correct control code without the bit change.

### BRIEF DESCRIPTION OF DRAWINGS

FIG. 1 is a block diagram showing a structure of a conventional test mode control circuit.

FIG. 2 is a block diagram showing a structure of a semiconductor device according to a first embodiment.

FIG. 3 is a block diagram showing a specific example of a Hamming distance determination circuit.

FIG. 4 is a flow chart for a test mode control processing.

FIG. 5 is a block diagram showing a modified structure of the Hamming distance determination circuit according to the present embodiment.

FIG. 6 is a diagram showing a test mode control code to which an error correction code is added.

FIG. 7 is a flow chart for a test mode control processing in the modification.

FIG. 8 is a block diagram showing a structure of a test mode control circuit according to a second embodiment.

FIG. 9 is a block diagram showing a structure of a test mode control circuit according to a third embodiment.

### NUMERICAL REFERENCES

1 Nonvolatile memory
2 Register
3 Fixed value generation unit
4 and 4a Hamming distance determination circuit
5 AND circuit
6 Test circuit
7 Selector
8 Access circuit
10 CPU
4-1, 4-2, . . . , 4-n EXOR circuit
41 Hamming distance calculation unit
45 Error correction circuit
46 Comparison circuit
401 Adder

### BEST MODE FOR CARRYING OUT THE INVENTION

Hereinafter, embodiments of the present invention are described with reference to the drawings.

### First Embodiment

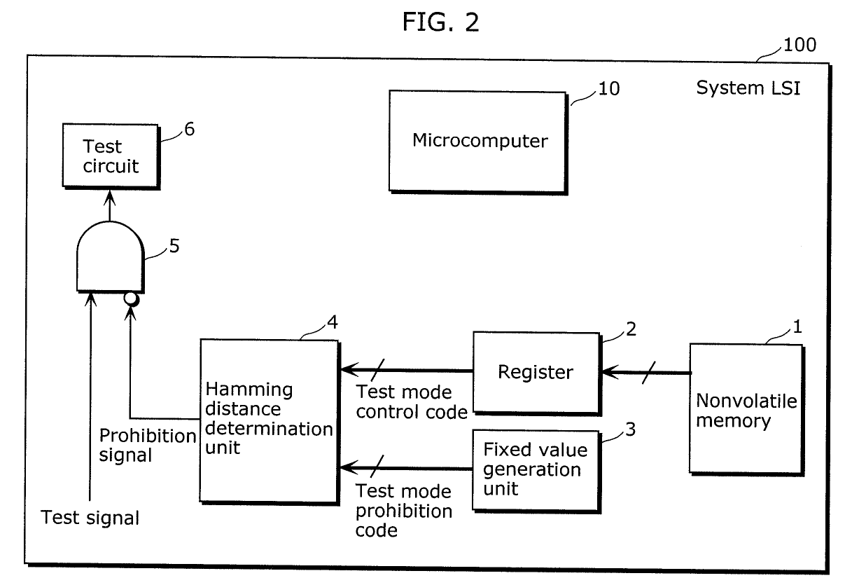

FIG. 2 is a block diagram showing a structure of a system LSI including a test mode control circuit according to a first embodiment of the present invention. In FIG. 2, a system LSI 100 is a semiconductor device having a test mode and including a nonvolatile memory 1, a register 2, a fixed value generation unit 3, a Hamming distance determination circuit 4, an AND circuit 5, a test circuit 6, and a microcomputer 10. Furthermore, the test mode control circuit is structured by a part of the nonvolatile memory 1, the register 2, the fixed value generation unit 3, the Hamming distance determination circuit 4, and the AND circuit 5.

The nonvolatile memory 1 stores, in a predetermined address, a test mode control code (also referred to as a test mode control flag) which permits or prohibits switching to the test mode. The test mode control code is set based on a need right after production in a factory or in maintenance. After shipment, the test mode control code which prohibits the switching to the test mode is set.

The register 2 holds a test mode control code read from the nonvolatile memory 1. For example, right after reset of the system LSI 100, the microcomputer 10 reads the test mode control code from the nonvolatile memory 1 and set it to the register 2.

The fixed value generation unit 3 generates the test mode prohibition code which is a fixed value. For example, the fixed value generation unit 3 is structured by a combination of wirings connected to a high level or a low level. The test mode prohibition code may be a predetermined fixed value such as, for example, 5 A in hexadecimal for 8 bits or 5 A5 A5 A5 A for 32 bits.

In the case where a Hamming distance between the test mode control code outputted from the register 2 and the test mode prohibition code outputted from the fixed value generation unit 3 (hereinafter, referred to as a fixed value) is equal to or less than a predetermined number, the Hamming distance determination circuit 4 outputs a prohibition signal which controls the switching to the test mode. Here, the predetermined number may be a value of approximately 2 bits in the case where the test mode control code is 8 bits or a value of approximately 5 bits in the case where the test mode control code is 32 bits. In the case where, for example, a failure or the like causes a bit change in a 32-bit test mode control code and the number of changed bits is equal to or less than the predetermined number, the Hamming distance determination circuit 4 outputs the prohibition signal which prohibits the switching to the test mode.

The AND circuit 5 is a mask circuit which masks the test signal which indicates the switching to the test mode based on the prohibition signal. In an example of FIG. 2, in the case where the prohibition signal is the high level which denotes the prohibition, the AND circuit 5 outputs the low level obtained by masking the test signal to the test circuit 6. In this way, the switching to the test mode is prohibited. Moreover, in the case where the prohibition signal is the low level which denotes the permission, the AND circuit 5 outputs the level of the test signal as-is to the test circuit 6. In this way, the switching to the test mode is permitted.

The test circuit 6 makes the switching to the test mode and performs various test operations when the test signal (high level) is inputted via the AND circuit. After the switching to the test mode, the system LSI 100 is further capable of changing each unit of the nonvolatile memory 1 and the like to an accessible mode for initialization or setting change in the system LSI 100.

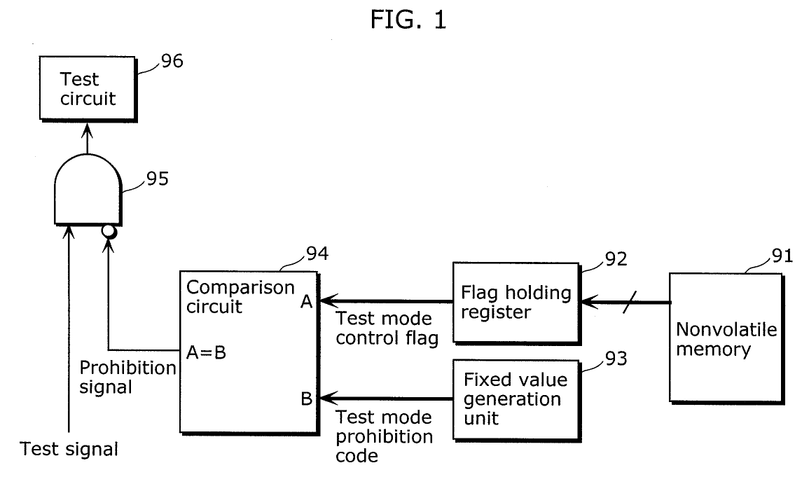

The different between the structure shown in FIG. 2 and the previously-described conventional structure shown in FIG. 1 is that the comparison circuit is replaced with the Hamming distance determination circuit. Accordingly, although the data of the test mode control flag stored in the nonvolatile memory changes, when the change is within the predetermined bit number, it is possible to maintain a test mode prohibition state.

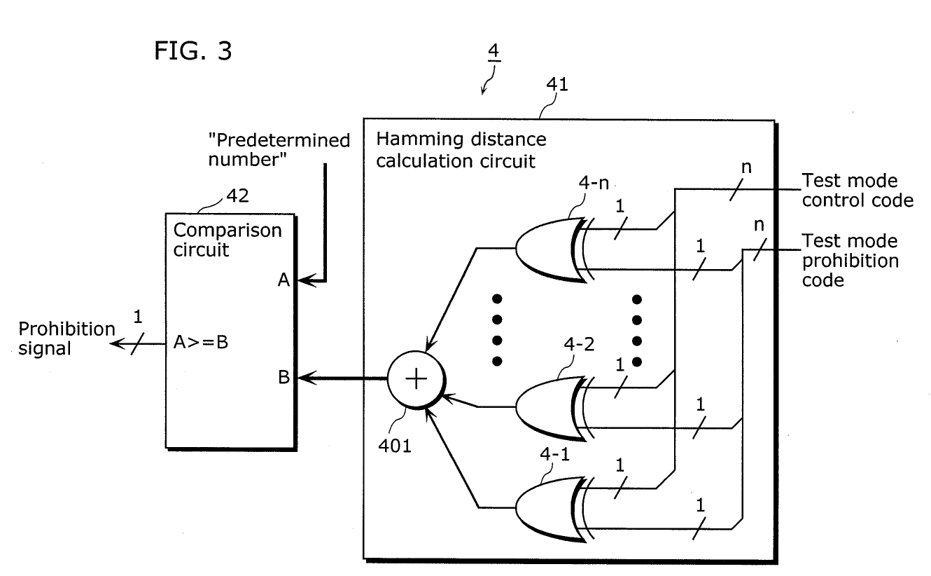

FIG. 3 is a block diagram showing a more specific circuit example of the Hamming distance determination circuit 4. In FIG. 3, the Hamming distance determination circuit 4 includes a Hamming distance calculation circuit 41 and a comparison circuit 42.

The Hamming distance calculation circuit 41 calculates a Hamming distance between the test mode control code of the register 2 and the fixed value of the fixed value generation unit 3. Therefore, the Hamming distance calculation circuit 41 includes n number of EXOR circuits 4-1 to 4-n and an adder 401. Here, n is equal to each bit number of the test code control code and the fixed value.

The EXOR circuits 4-1 to 4-n respectively determine whether or not a bit value in the test mode control code and a corresponding bit value in the fixed value match.

The adder 401 adds outputs of n number of the EXOR circuits 4-1 to 4-n. This leads to output the mismatched bit number from among n bits corresponding to the test mode control code and the fixed value, that is, the Hamming distance.

The comparison circuit 42 determines whether or not the Hamming distance is equal to or less than the predetermined number by comparing the predetermined number and the calculated Hamming distance. In the case where the Hamming distance is equal to or less than the predetermined number, the prohibition signal is made active (high level). In the case where the Hamming distance is greater than the predetermined number, the prohibition signal is made inactive (low level).

An operation of the semiconductor device structured as above is described.

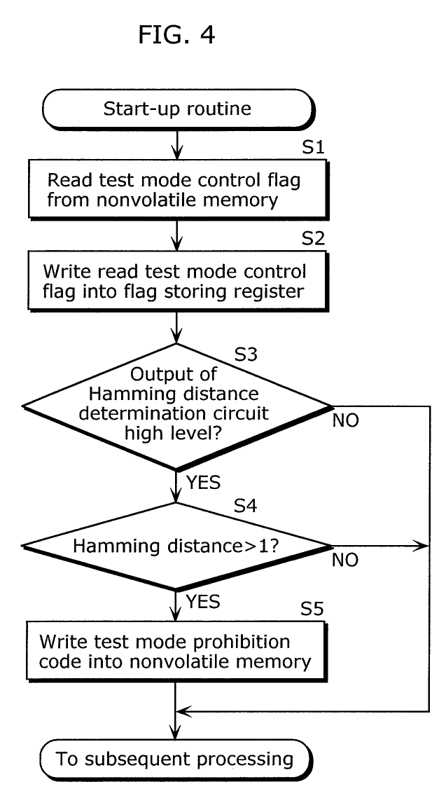

FIG. 4 is a flow chart showing a test mode control processing in the above-mentioned semiconductor device.

In FIG. 4, when the system LSI 100 is started up, the microcomputer 10 initially reads the test mode control code from the nonvolatile memory 1 (S1) and writes the read test mode control code into the register 2 (S2). Since this leads the Hamming distance determination circuit 4 to output the prohibition signal based on the Hamming distance, even when error-bits of the test mode control code are equal to or less than the predetermined number, it is possible to prohibit the switching to the test mode.

Next, the microcomputer 10 determines whether or not the output of the Hamming distance determination circuit is the high level (prohibition) (S3). In the case where the output of the Hamming distance determination circuit 4 is the high level, that is, in the case where the Hamming distance between the data of the test mode control flag stored in the nonvolatile memory 1 and the fixed value is equal to or less than the predetermined number, the microcomputer 10 determines whether or not the Hamming distance outputted by the adder 401 is 1 or more (S4). In the case where the Hamming distance is I or more, that is, in the case where the bit change occurs in the test mode control code which denotes the prohibition, the microcomputer 10 writes the fixed value into the nonvolatile memory 1 (S5).

Since this leads to write back the fixed value even in the case where any factors cause a change of few bits in the test mode control code which indicates the prohibition of the switching to the test mode, the test mode control code being stored in the nonvolatile memory 1, it is possible to lessen the possibility that the prohibition of the execution of test mode is canceled by a change of data of the nonvolatile memory 1.

As described above, in the case where the Hamming distance between the test mode control code and the fixed value is equal to or less than the predetermined number, that is, in the case where the failure or the like causes the bit change in the test mode control code and the number of the changed bits is equal to or less than the predetermined number, the semiconductor device according to the present embodiment prohibits the switching to the test mode. For example, even in the case where the bit change equal to or less than the predetermined number occurs in the test mode control code which denotes the prohibition of the switching to the test mode, canceling the prohibition of the switching to the test mode is prevented. As a result, the disclosure and falsification of the circuit information are prevented, thereby securing the security.

Furthermore, even in the case where the bit change equal to or less than the predetermined number occurs in the test mode control code which denotes the permission for the switching to the test mode, the switching to the test mode is not prohibited. Consequently, it is possible to lower the probability that the test mode is prohibited right after production, thereby preventing a decline of the yield.

Further, Since the fixed value is written back, as the test mode control code, to the nonvolatile memory 1 even in the case where any factors cause the change of few bits in the test mode control code which indicates the prohibition of the switching to the test mode, it is possible to further lessen the possibility that the prohibition of the execution of test mode is accidentally canceled by the change of data of the nonvolatile memory 1.

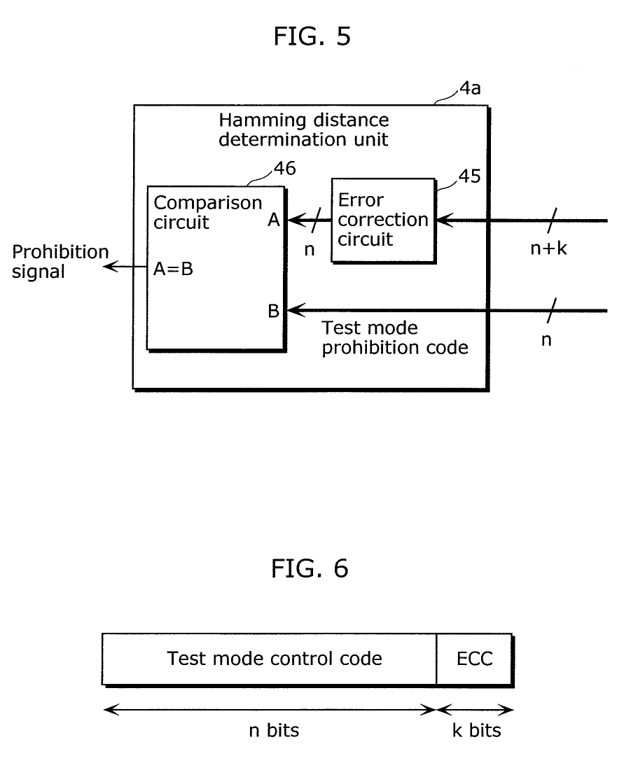

Subsequently, a modification of the present embodiment is described. FIG. 5 is a block diagram showing a modification of the structure of the Hamming distance determination circuit 4 shown in FIG. 3. In FIG. 5, a Hamming distance determination circuit 4a includes an error correction circuit 45 and a comparison circuit 46. Additionally, as shown in FIG. 6, it is assumed that an error correction code for correcting the number of bit errors equal to or less than the predetermined number is added to the test mode control code. The nonvolatile memory 1 and the register 2 store the test mode control code to which the error correction code is added.

The error correction circuit 45 performs, on the test mode control code to which the error correction code is added, an error correction processing for correcting the number of bit errors equal to or less than the predetermined number. Furthermore, along with the error correction processing, the error correction circuit 45 detects the number of bit errors at least equal to or less than the predetermined number.

The comparison circuit 46 determines whether or not the error-corrected test mode control code and the fixed value of the fixed value generation unit 3 match by comparing the error-corrected test mode and the fixed value.

Accordingly, instead of directly calculating the Hamming distance, it is possible to determine whether or not the Hamming distance is equal to or less than the predetermined number by simply comparing the error-corrected test mode control code and the fixed value.

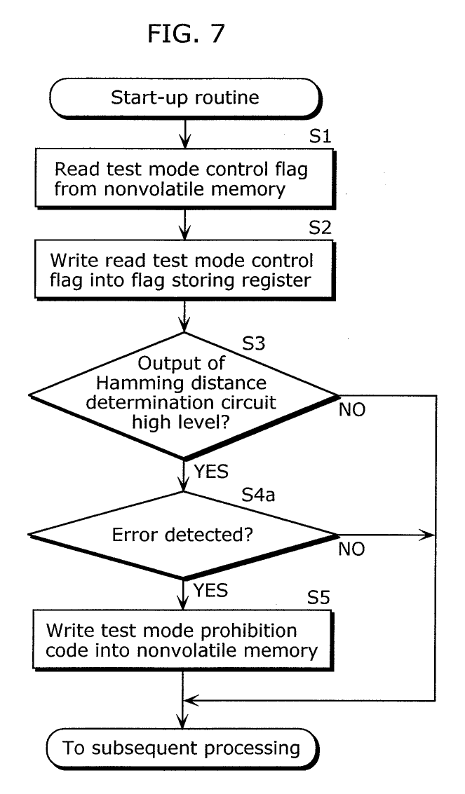

Moreover, FIG. 7 is a flow chart showing a test mode control processing in the semiconductor device including the Hamming distance determination circuit 4a shown in FIG. 5. The flow chart of FIG. 7 differs from FIG. 4 in that there is a step S4a instead of a step S4. The following description mainly focuses not on the same elements but on the different elements. In step S4a, the microcomputer 10 determines whether an error is detected with an error detection signal from the error correction circuit 45, that is, whether or not any factors cause the change of few bits in the test mode control code which indicates the prohibition of the switching to the test mode.

It should be noted that although the case in which the switching to the test mode is prohibited in the case where the Hamming distance is equal to or less than the predetermined number is described in the above-mentioned present embodiment, it is possible to configure that the switching to the test mode is permitted in the case where the Hamming distance is equal to or less than the predetermined number. In this case, it is possible to configure that the comparison circuit 42 of FIG. 3 outputs the high level in case of A<B, and it is possible to configure that the comparison circuit 46 of FIG. 5 outputs the high level in the case where A and B do not match. In addition, although the case in which the microcomputer 10 is a main operating body is described in FIG. 4 and FIG. 7, it is possible to include hardware other than the microcomputer 10 as the main operating body.

### Second Embodiment

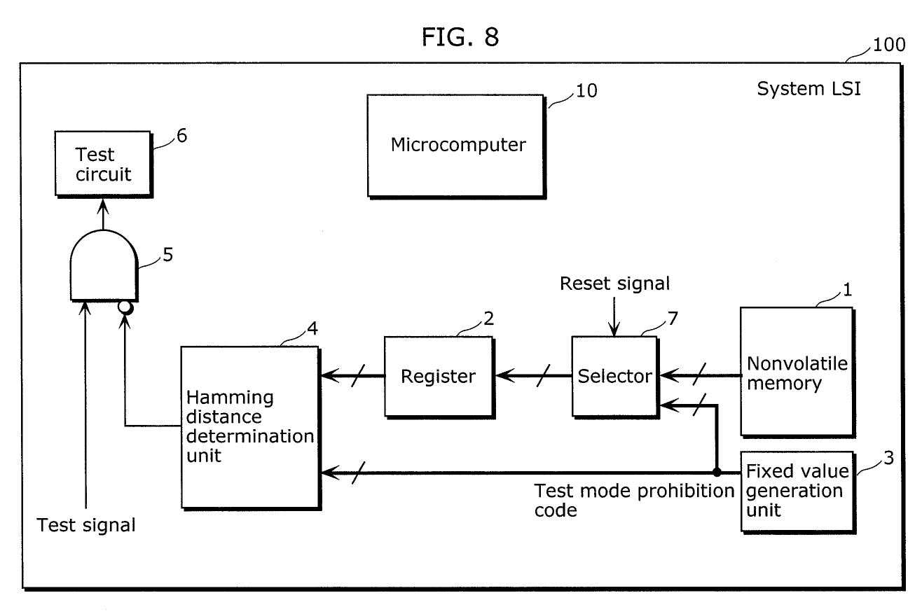

FIG. 8 is a block diagram showing a structure of a semiconductor device according to a second embodiment of the present invention. FIG. 1 differs from FIG. 2 in that a selector 7 is added and that an output signal of the selector 7 is inputted to the register 2. The following description mainly focuses not on the same elements but on the different elements.

The test mode control code of the nonvolatile memory 1 and the fixed value of the fixed value generation unit 3 are inputted to the selector 7 which selects the test mode control code when a reset signal is inactive, and which selects the fixed value when the reset signal is active. The register 2 holds the fixed value as an initial value when the semiconductor device is reset, and holds the test mode control code of the nonvolatile memory 1 after the reset of the semiconductor device.

As a result, in a period from a beginning of the reset till when the test mode control code is set to the register 2, the Hamming distance determination circuit 4 makes the prohibition signal active and can prevent the prohibition state from being canceled. For example, it is possible to prevent the switching to the test mode by abusing the reset signal for disclosing and falsifying the data of the nonvolatile memory 1, and to realize the test mode control with much better security.

It should be noted that the modification of the first embodiment may be applied to the present embodiment.

### Third Embodiment

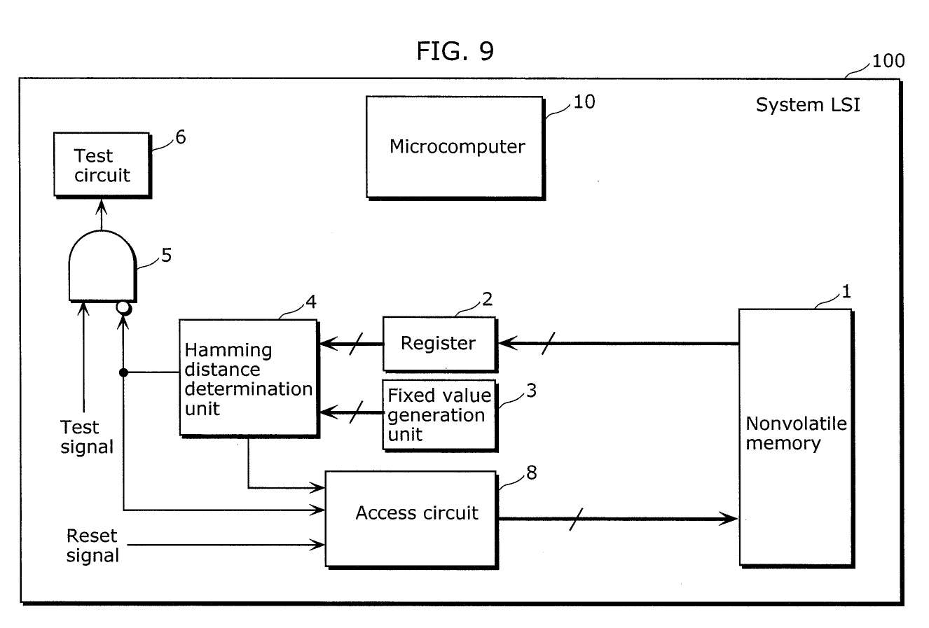

FIG. 9 is a block diagram showing a structure of a semiconductor device according to a third embodiment of the present invention. FIG. 9 differs from FIG. 2 in that an access circuit 8 is added. The following description mainly focuses not on the same elements but on the different elements.

The access circuit 8 is a hardware circuit which performs the operation shown in FIG. 4 or FIG. 7. In other words, the access circuit 8 to which the reset signal is inputted automatically generates a read signal corresponding to an address where the test mode control code of the nonvolatile memory 1 is stored when the reset is released, and writes the test mode control code into the register 2. After writing the test mode control code is completed, in the case where the output of the Hamming distance determination circuit 4 is the high level and the Hamming distance is equal to or more than 1, that is, in the case where the Hamming distance between the test mode control code stored in the nonvolatile memory 1 and a test mode prohibition code is equal to or less than the predetermined number and the bit change occurs in the test mode control code, a writing signal corresponding to the address where a test mode control flag of the nonvolatile memory 1 is stored is generated, and the test mode prohibition code (fixed value) is written into the nonvolatile memory 1.

Since this leads to write back the test mode prohibition code again even in the case where any factors cause a change of few bits in a flag which indicates the prohibition of the test mode, the flag being stored in the nonvolatile memory 1, it is possible to lessen the possibility that the prohibition of the execution of test mode is canceled by the change of data of the nonvolatile memory 1.

It should be noted that the selector 7 shown in FIG. 8 may be added to the structure of FIG. 9.

In addition, the modifications of the first embodiment and the second embodiment may be applied to the present embodiment.

### INDUSTRIAL APPLICABILITY

The test mode control circuit according to the present invention is useful for all of the semiconductor devices which control the prohibition of the execution of test mode with the use of the nonvolatile memory.

In particular, since it is possible to prevent the disclosure and falsification of internal information by using the test mode, it is useful for the semiconductor device including highly confidential data, program, and the security circuit.

1. A semiconductor device having a test mode, said device comprising:
a nonvolatile memory which stores a control code in a predetermined address;
a generation unit operable to generate a fixed value; and
a control unit operable to control switching to the test mode depending on whether or not a Hamming distance between the control code and the fixed value is equal to or less than a predetermined number.

2. The semiconductor device according to claim 1,
wherein said control unit includes:
a calculation unit operable to calculate the Hamming distance between the control code and the fixed value generated by said generation unit;
a comparison unit operable to determine whether or not the Hamming distance is equal to or less than the predetermined number by comparing the calculated Hamming distance and the predetermined number; and
a prohibition unit operable to prohibit the switching to the test mode when the Hamming distance is determined to be equal to or less than the predetermined number.

3. The semiconductor device according to claim 1,
wherein an error correction code for correcting the number of bit errors equal to or less than the predetermined number is added to the control code, and
said control unit includes:
an error correction unit operable to perform an error correction processing on the control code by using the error correction code;
a comparison unit operable to determine whether or not the error-corrected control code and the fixed value generated by said generation unit match by comparing the error-corrected control code and the fixed value; and
a prohibition unit operable to prohibit the switching to the test mode when the error-corrected control code and the fixed value are determined to match.

4. The semiconductor device according to claim 1, further comprising:
a register for storing data;
a first setting unit operable to set the fixed value, as an initial value, to said register when said semiconductor device is reset; and
a second setting unit operable to read the control code from said nonvolatile memory and to set the read control code to said register after said semiconductor device is reset,
wherein said control unit is operable to control the switching to the test mode according to a Hamming distance between the data held in said register and the fixed value.

5. The semiconductor device according to claim 1, further comprising
wherein said semiconductor device further includes a writing unit operable to write the fixed value into said nonvolatile memory when the Hamming distance is equal to or less than the predetermined number.

6. The semiconductor device according to claim 5, further comprising
wherein the semiconductor device includes:
a memory which stores a program in which a function of said writing unit is described; and
a microcomputer which executes the program, and
said writing unit is realized through the execution of the program by said microcomputer.

7. A test mode control circuit which is included in a semiconductor device having a test mode, said circuit comprising:
a nonvolatile memory which stores a control code in a predetermined address;
a generation unit operable to generate a fixed value; and
a control unit operable to control switching to the test mode depending on whether or not a Hamming distance between the control code and the fixed value is equal to or less than a predetermined number.

8. A test mode control method for a semiconductor device having a test mode, said method comprising:
a step of reading a control code stored in a predetermined address of a nonvolatile memory; and
a step of controlling switching to the test mode depending on whether or not a Hamming distance between the control code and the fixed value is equal to or less than a predetermined number.

9. A program readable by a microcomputer in a semiconductor device having a test mode, said program causing a microcomputer to execute:
a step of reading a control code stored in a predetermined address of a nonvolatile memory; and
a step of controlling switching to the test mode depending on whether or not a Hamming distance between the control code and the fixed value is equal to or less than a predetermined number.

10. The semiconductor device according to claim 2, further comprising:
a register for storing data;
a first setting unit operable to set the fixed value, as an initial value, to said register when said semiconductor device is reset; and
a second setting unit operable to read the control code from said nonvolatile memory and to set the read control code to said register after said semiconductor device is reset,
wherein said control unit is operable to control the switching to the test mode according to a Hamming distance between the data held in said register and the fixed value.

11. The semiconductor device according to claim 3, further comprising:
a register for storing data;
a first setting unit operable to set the fixed value, as an initial value, to said register when said semiconductor device is reset; and
a second setting unit operable to read the control code from said nonvolatile memory and to set the read control code to said register after said semiconductor device is reset,
wherein said control unit is operable to control the switching to the test mode according to a Hamming distance between the data held in said register and the fixed value.

12. The semiconductor device according to claim 2, further comprising
wherein said semiconductor device further includes a writing unit operable to write the fixed value into said nonvolatile memory when the Hamming distance is equal to or less than the predetermined number.

13. The semiconductor device according to claim 12, further comprising
wherein the semiconductor device includes:
a memory which stores a program in which a function of said writing unit is described; and
a microcomputer which executes the program, and
said writing unit is realized through the execution of the program by said microcomputer.

14. The semiconductor device according to claim 3, further comprising
wherein said semiconductor device further includes a writing unit operable to write the fixed value into said nonvolatile memory when the Hamming distance is equal to or less than the predetermined number.

15. The semiconductor device according to claim 14, further comprising
wherein the semiconductor device includes:
a memory which stores a program in which a function of said writing unit is described; and
a microcomputer which executes the program, and
said writing unit is realized through the execution of the program by said microcomputer.
